(19) United States
(12) Patent Application Publication
(10) Pub. No.: US 2026/0018866 A1
(43) Pub. Date: Jan. 15, 2026

(54) WAVELENGTH BEAM COMBINING DEVICE, DIRECT DIODE LASER DEVICE, AND LASER PROCESSING MACHINE

(71) Applicant: NICHIA CORPORATION, Anan-shi (JP)

(72) Inventors: Satoshi TANABE, Yokohama-shi (JP); Norihiro DEJIMA, Yokohama-shi (JP)

(73) Assignee: NICHIA CORPORATION, Anan-shi (JP)

(21) Appl. No.: 19/259,492

(22) Filed: Jul. 3, 2025

(30) Foreign Application Priority Data
Jul. 10, 2024 (JP) 2024-111003

(51) Int. Cl. H01S 5/40; B23K 26/06; G02B 27/09; G02B 27/28

(52) U.S. Cl. CPC H01S 5/4012; B23K 26/0643; G02B 27/0944; G02B 27/283; G02B 27/286

(57) ABSTRACT

A wavelength beam combining device for combining laser beams having different peak wavelengths includes: a first optical component separating the laser beams into first polarization beams linearly polarized in a first polarization direction and second polarization beams linearly polarized in a second polarization direction orthogonal to the first polarization direction; a first polarization conversion element converting the second polarization beams into third polarization beams linearly polarized in the first polarization direction; first and second mirrors reflecting the first and third polarization beams, respectively; a first diffraction element receiving the first polarization beams and diffracting them to form a first wavelength-combined beam coaxially combined; a second diffraction element receiving the third polarization beams and diffracting them to form a second wavelength-combined beam in which the third polarization beams are coaxially combined; and a second optical component on which the first and second wavelength-combined beams are incident.

### CROSS REFERENCE TO RELATED APPLICATION

This application claims priority to Japanese Patent Applications No. 2024-111003, filed on Jul. 10, 2024, the entire contents of which are hereby incorporated by reference.

### BACKGROUND

### Technical Field

The present disclosure relates to a wavelength beam combining device, a direct diode laser device, and a laser processing machine.

### Background Art

High-power and high-brightness laser beams are used to perform processing such as cutting, drilling, and marking on various types of materials or weld metal materials. Some carbon dioxide gas laser processing machines and some YAG solid laser processing machines, which have been used for such laser processing in the related art, are being replaced with a fiber laser processing machine having a high energy conversion efficiency. A laser diode (hereinafter, simply referred to as an LD) is used as a pump light source of a fiber laser processing machine. In recent years, with increasing output of the LD, technology has been developed to use the LD not as the pump light source but as a light source of a laser beam with which a material is directly irradiated and processed. Such technology is referred to as direct diode laser (DDL) technology.

U.S. Pat. No. 6,192,062 discloses an example of a light source device that increases light output by combining a plurality of laser beams having different peak wavelengths emitted from a plurality of LDs. Coaxially combining a plurality of laser beams of different wavelengths is referred to as “wavelength beam combining (WBC)” or “spectral beam combining (SBC)” and may be used, for example, to increase light output and brightness of a DDL device.

Japanese Patent Application Publication No. 2023-088438 A discloses a wavelength beam combining device in which a plurality of diffraction gratings are disposed in series on an optical path.

### SUMMARY

There is a demand for a wavelength beam combining device that can combine a plurality of laser beams having peak wavelengths different from each other with small loss.

A wavelength beam combining device according to certain embodiments of the present disclosure is a wavelength beam combining device configured to combine a plurality of laser beams having different peak wavelengths, the wavelength beam combining device including: a first optical component configured to separate the plurality of laser beams into a plurality of first polarization beams linearly polarized in a first polarization direction and a plurality of second polarization beams linearly polarized in a second polarization direction orthogonal to the first polarization direction; a first polarization conversion element configured to convert the plurality of second polarization beams into a plurality of third polarization beams linearly polarized in the first polarization direction; a plurality of first mirrors each configured to reflect a respective one of the plurality of first polarization beams towards a first diffraction position; a plurality of second mirrors each configured to reflect a respective one of the plurality of third polarization beams towards a second diffraction position; a first diffraction element configured to receive, at the first diffraction position, the plurality of first polarization beams reflected by the plurality of first mirrors and diffract the plurality of first polarization beams to form a first wavelength-combined beam in which the plurality of first polarization beams are coaxially combined; a second diffraction element configured to receive, at the second diffraction position, the plurality of third polarization beams reflected by the plurality of second mirrors and diffract the plurality of third polarization beams to form a second wavelength-combined beam in which the plurality of third polarization beams are coaxially combined; and a second optical component on which the first wavelength-combined beam and the second wavelength-combined beam are incident.

A direct diode laser device according to the present disclosure includes the wavelength beam combining device and a laser light source configured to emit a plurality of laser beams parallel to each other.

A laser processing machine according to the present disclosure includes at least one direct diode laser device being the direct diode laser device described above; an optical transmission fiber to be coupled to a laser beam emitted from the at least one direct diode laser device; and a processing head connected to the optical transmission fiber.

According to an embodiment of the present disclosure, it is possible to provide a wavelength beam combining device that can combine a plurality of laser beams having different peak wavelengths with a small loss.

### BRIEF DESCRIPTION OF DRAWINGS

FIG. 1 is a diagram schematically illustrating a configuration of a wavelength beam combining device according to an exemplary embodiment of the present disclosure.

FIG. 2 is a perspective view schematically illustrating a configuration example and a function of a polarization beam splitter.

FIG. 3A is a perspective view schematically illustrating a configuration example of a diffraction grating.

FIG. 3B is a cross-sectional view schematically illustrating a configuration example of the diffraction grating.

FIG. 4 is a diagram schematically illustrating a modified example of the wavelength beam combining device illustrated in FIG. 1.

FIG. 5 is a diagram schematically illustrating another configuration of the wavelength beam combining device according to the exemplary embodiment of the present disclosure.

FIG. 6 is a diagram schematically illustrating still another configuration of the wavelength beam combining device according to the exemplary embodiment of the present disclosure.

FIG. 7 is a diagram schematically illustrating still another configuration of the wavelength beam combining device according to the exemplary embodiment of the present disclosure.

FIG. 8 is a diagram schematically illustrating a diffraction region in the wavelength beam combining device of FIG. 7.

FIG. 9 is a diagram schematically illustrating still another configuration of the wavelength beam combining device according to the exemplary embodiment of the present disclosure.

FIG. 10 is a diagram schematically illustrating a diffraction region in the wavelength beam combining device of FIG. 9.

FIG. 11 is a schematic diagram illustrating a configuration of a direct diode laser device according to an exemplary embodiment of the present disclosure.

FIG. 12 is a schematic diagram illustrating a configuration of a laser processing machine according to an exemplary embodiment of the present disclosure.

### DETAILED DESCRIPTION

Hereinafter, a wavelength beam combining device, a direct diode laser device, and a laser processing machine according to certain embodiments of the present disclosure will be described with reference to the drawings. Parts having the same reference characters appearing in the plurality of drawings indicate identical or equivalent parts.

The embodiments described below are examples embodying the technical ideas of the present invention, but the present invention is not limited to the described embodiments. The descriptions of dimensions, materials, shapes, relative arrangements, and the like of components are not intended to limit the scope of the present invention thereto but intended to be illustrative. The sizes and a positional relationship of components illustrated in the drawings may be exaggerated to facilitate understanding.

In the present description and the scope of claims, a polygon refers to a polygonal shape such as a triangle or a quadrangle, including a shape in which a corner of the polygon is rounded, chamfered, beveled, or coved. A polygon includes not only a polygonal shape with such modification at its corner (an end of a side) but also a polygonal shape with modification at an intermediate part of a side. In other words, a polygon-based shape with partial modification is included in the interpretation of “polygon” described in the present description and the scope of claims.

### EMBODIMENTS

### Wavelength Beam Combining Device

### First Embodiment

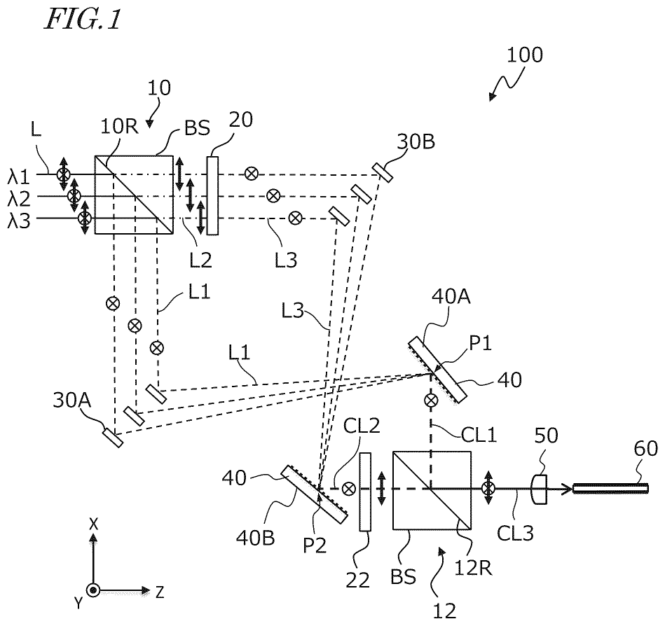

First, a configuration example of a wavelength beam combining device according to a first embodiment of the present disclosure will be described with reference to FIG. 1.

FIG. 1 is a diagram schematically illustrating a configuration example of a wavelength beam combining device 100 according to the present embodiment. In each drawing including FIG. 1, an X-axis, a Y-axis, and a Z-axis orthogonal to each other are schematically illustrated for reference. The direction of an arrow on the X-axis is referred to as a +X direction, and an opposite direction thereof is referred to as a −X direction. When the ±X directions are not distinguished from each other, the ±X directions are simply referred to as X directions. The same applies to a Y direction and a Z direction. This does not limit the orientation of the wavelength beam combining device 100 in use, and the orientation of the wavelength beam combining device 100 can be used in any appropriate orientation.

First, a schematic configuration of the wavelength beam combining device 100 in the example of FIG. 1 will be described.

The wavelength beam combining device 100 is a device that combines a plurality of laser beams L having mutually different peak wavelengths, and includes a first optical component 10 and a second optical component 12 each of which separates or combines light, a first polarization conversion element 20 and a second polarization conversion element 22 that change a polarization state of incident light and emit the light, a plurality of first mirrors 30A and a plurality of second mirrors 30B that change a traveling direction of the incident light and reflect the light, and a first diffraction element 40A and a second diffraction element 40B that function as diffraction gratings.

The first optical component 10 separates the plurality of laser beams L into a plurality of first polarization beams L1 linearly polarized in a first polarization direction (Y direction) and a plurality of second polarization beams L2 linearly polarized in a second polarization direction (X direction) orthogonal to the first polarization direction (Y direction). The first optical component 10 in the example of FIG. 1 is constituted by a polarization beam splitter BS. As described below, the first optical component 10 is not limited to a single component, and may include other optical elements such as a component that forms a reflection surface and a component that shifts an optical path, in addition to the polarization beam splitter BS.

The first polarization conversion element 20 converts the plurality of second polarization beams L2 into a plurality of third polarization beams L3 linearly polarized in the first polarization direction (Y direction).

The plurality of first mirrors 30A are disposed to reflect each of the plurality of first polarization beams L1 towards the first diffraction position P1.

The plurality of second mirrors 30B are disposed to reflect each of the plurality of third polarization beams L3 towards the second diffraction position P2.

The first diffraction element 40A receives the plurality of first polarization beams L1, reflected by the plurality of first mirrors 30A, at the first diffraction position P1, and diffracts the plurality of first polarization beams L1 to form a first wavelength-combined beam CL1 in which the plurality of first polarization beams L1 are coaxially combined.

The second diffraction element 40B receives the plurality of third polarization beams L3 reflected by the plurality of second mirrors 30B at the second diffraction position P2, and diffracts the plurality of third polarization beams L3 to form a second wavelength-combined beam CL2 in which the plurality of third polarization beams L3 are coaxially combined.

The second polarization conversion element 22 in the example illustrated in FIG. 1 converts the polarization direction of the second wavelength-combined beam CL2 from the first polarization direction (Y direction) into the second polarization direction (X direction in the example illustrated in FIG. 1) orthogonal to the first polarization direction. The second polarization conversion element 22 may be disposed to convert the polarization direction of the first wavelength-combined beam CL1 from the first polarization direction (Y direction) into a direction (Z direction in the example illustrated in FIG. 1) orthogonal to the first polarization direction. The important point is that the second polarization conversion element 22 causes the polarization direction of the first wavelength-combined beam CL1 and the polarization direction of the second wavelength-combined beam CL2 to be orthogonal to each other, thereby enabling polarization-combining (multiplexing) by the second optical component 12.

The second optical component 12 is disposed such that the first wavelength-combined beam CL1 and the second wavelength-combined beam CL2 are incident on the second optical component 12. In the example illustrated in FIG. 1, the second optical component 12 includes a polarization beam splitter BS that coaxially combines the first wavelength-combined beam CL1 and the second wavelength-combined beam CL2 and emits the combined beam as a third wavelength-combined beam CL3. In a case in which the second optical component 12 does not perform polarization-combining by the polarization beam splitter BS, the second optical component 12 may be constituted by a condensing lens 50 without including the polarization beam splitter BS. Such an example will be described below.

In the example of FIG. 1, the third wavelength-combined beam CL3 condensed by the condensing lens 50 enters (is optically coupled to) a core of an optical fiber 60.

In the wavelength beam combining device 100 according to the present embodiment, a single diffraction grating, instead of a plurality of diffraction gratings, is placed on the optical path of each of the polarization beams (L1 and L3). Therefore, optical loss due to diffraction is reduced.

Further, in the present embodiment, a plurality of laser beams L may be incident, parallel to each other, on the first optical component 10. A polarization separation characteristic of the first optical component 10 depends on an incident angle, and thus the polarization separation of the laser beams L can be efficiently performed by causing the laser beams L to be incident, parallel to each other, on the first optical component 10. Each of the plurality of light beams separated by the first optical component 10 may be incident on the target first diffraction element 40A or the target second diffraction element 40B at a predetermined angle by a corresponding one of the plurality of first mirrors 30A or a corresponding one of the plurality of second mirrors 30B.

Hereinafter, the laser beam L and the components of the wavelength beam combining device 100 will be described in detail.

### Laser Beam L

The plurality of laser beams L have different peak wavelengths within, for example, a predetermined wavelength range of 50 nm or less. The predetermined wavelength range corresponds to at least a part of a wavelength range in which light absorptance of a material to be processed is high. When an absolute value of a difference between a maximum value and a minimum value of the peak wavelengths is, for example, equal to or smaller than 50 nm, optical system elements having wavelength-dependent optical characteristics, such as the polarization beam splitter BS, the polarization conversion elements 20 and 22, and the condensing lens 50, can be commonly used for a plurality of light beams having different peak wavelengths, regardless of the wavelengths of the light beams. For example, in a case in which the material to be processed is formed of copper, the predetermined wavelength range may be, for example, in a range of 430 nm to 480 nm.

In FIG. 1, three laser beams L having peak wavelengths λ1, λ2, and λ3 different from each other are illustrated. The number of laser beams L is not limited to this example, and may be two or may be four or more. With a greater number, e.g. 10 or more, of laser beams L, output and power density of the wavelength-combined beam CL3 obtained by combining the plurality of laser beams L can be increased. When an interval between the peak wavelengths of the plurality of laser beams L is narrowed, the number of laser beams L in a predetermined wavelength range can be increased.

Hereinafter, the peak wavelength of the plurality of laser beams L to be combined is also denoted by λn. Here, “n” is an integer of 1 or more, and is used as a numerical value for distinguishing the plurality of laser beams L. In the example illustrated in FIG. 1, a relationship of λ1<λ2<λ3 is established.

In FIG. 1, each laser beam L is indicated by a simple straight line. An actual laser beam L is a light beam having an intensity distribution in a plane orthogonal to the traveling direction. The intensity distribution can be approximated by a distribution function such as a Gaussian distribution in a plane orthogonal to the traveling direction of the light beam. The diameter of the light beam is defined, for example, by the size of a cross-sectional area having an intensity 1/e² or more times the intensity at the center of the beam. e is the base of a natural logarithm. In the present disclosure, the laser beam L is collimated by an optical system such as a collimator lens. In the drawings, a central axis of the light beam is represented by a straight line in order to schematically illustrate the traveling direction of a collimated light beam such as the laser beam L. These straight lines may be considered to indicate light rays passing through the center of respective light beams.

The polarization state of the laser beam L may vary depending on, for example, a gain medium, a resonator, and an oscillation scheme of the laser light source. In addition, the polarization state of the laser beam L, which is in a specific polarization state at the stage of being emitted from the semiconductor laser device, may be changed or depolarized while passing through a transmission medium such as an optical fiber, for example.

Each laser beam L is, for example, in a non-polarized state. For example, as described above, each laser beam L is obtained by emitting each laser beam L from the semiconductor laser device via the optical fiber.

In the present disclosure, “non-polarized light” means light that is not linearly polarized in a predetermined direction. As described above, “non-polarized light” in a broad sense can include circularly polarized light and elliptically polarized light. Further, a mixed state of linearly polarized light in which the polarization direction randomly or regularly changes depending on time or place is also included in the “non-polarized light.”

### First Optical Component

The first optical component 10 in the example of FIG. 1 is the polarization beam splitter BS. The polarization beam splitter BS is formed of, for example, quartz or synthetic quartz. The first optical component 10 has a polarization surface 10R for separating each incident laser beam L into light beams in different polarization states. Transmittance and reflectance of the polarization surface 10R differ depending on the polarization state of the laser beam L. The polarization surface 10R of the first optical component 10 can selectively reflect a polarization component linearly polarized in a predetermined direction and transmit a polarization component linearly polarized in a direction orthogonal to the predetermined direction. The polarization surface 10R is provided with, for example, a dielectric multilayer film having polarized light dependency.

In the example illustrated in FIG. 1, the polarization surface 10R of the first optical component 10 is perpendicular to the XZ plane, and the normal line of the polarization surface 10R is in a plane parallel to the XZ plane. The traveling direction of the laser beam L is parallel to the XZ plane. In the present description, light linearly polarized in the Y direction, which is a direction perpendicular to the XZ plane, is referred to as “S-polarized light,” and light linearly polarized in a direction parallel to the XZ plane is referred to as “P-polarized light.” In the present description, the polarization direction of the S-polarized light is also referred to as a “first polarization direction,” and the polarization direction of the P-polarized light is also referred to as a “second polarization direction.” The second polarization direction is orthogonal to the first polarization direction.

In the accompanying drawings, in principle, a symbol with a cross symbol surrounded by a small circle represents “S-polarized light,” and a symbol with a double-headed arrow represents “P-polarized light.” Because the polarization direction of the “P-polarized light” is parallel to the XZ plane and is perpendicular to the traveling direction of the light, when the traveling direction of the light is rotated by reflection or diffraction while remaining parallel to the XZ plane, the polarization direction of the “P-polarized light” is also rotated in a plane parallel to the XZ plane. Therefore, in the present description, the “second polarization direction” is defined as a direction perpendicular to the traveling direction of light and perpendicular to the first polarization direction.

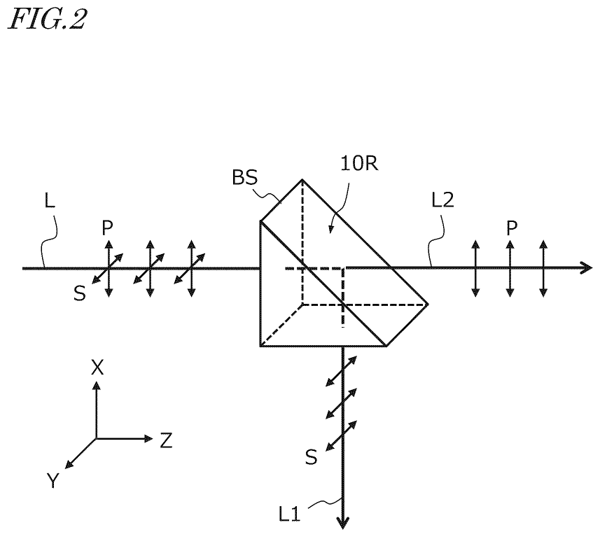

FIG. 2 is a perspective view schematically illustrating a configuration example and a function of the polarization beam splitter BS functioning as the first optical component 10. Because FIG. 2 is a perspective view, the orientation of the “S-polarized light” is also indicated by a double-headed arrow. In the example of FIG. 2, the laser beam L including the S-polarized light and the P-polarized light travels in the positive direction of the Z-axis and enters the polarization beam splitter BS. As illustrated in FIG. 2, the polarization surface 10R of the polarization beam splitter BS reflects an S-polarization component of each of the laser beams L and transmits a P-polarization component of each of the laser beams L. Therefore, the polarization surface 10R of the polarization beam splitter BS separates the plurality of laser beams L into a plurality of first polarization beams L1, which correspond to S-polarized light, and a plurality of second polarization beams L2, which correspond to P-polarized light. The plurality of first polarization (S-polarized) beams L1 reflected by the polarization surface 10R of the polarization beam splitter BS travel in the −X direction, and the plurality of second polarization (P-polarized) beams L2 transmitted through the polarization surface 10R of the polarization beam splitter BS travel in the +Z direction.

Each laser beam L may be incident on the polarization surface 10R at an incident angle in a range of, for example, 40° to 50°, more preferably in a range of 42° to 48°. The closer the incident angle is to 45°, the higher the separation efficiency of separating the corresponding first polarization beam L1 and second polarization beam L2 from each laser beam L is.

When the plurality of laser beams L incident on the polarization beam splitter BS are “non-polarized,” the laser beams L are separated into a first polarization (S-polarized) beam L1 and a second polarization (P-polarized) beam L2. However, even if the laser beam L is linearly polarized light in which S-polarized light and P-polarized light are combined, such a laser beam L is separated into the first polarization (S-polarized) beam L1 and the second polarization (P-polarized) beam L2 unless the polarization direction of the linearly polarized light is parallel to any of the X direction and the Y direction. Further, even if the plurality of laser beams L incident on the polarization beam splitter BS are linearly polarized in different directions, the plurality of laser beams L can be separated into the plurality of first polarization (S-polarized) beams L1 and the plurality of second polarization (P-polarized) beams L2 as a whole. Therefore, unless all of the plurality of laser beams L incident on the polarization beam splitter BS are linearly polarized in the same one of the X direction and the Y direction, polarization separation by the polarization beam splitter BS can be achieved, and thus such a plurality of laser beams L are regarded as being “non-polarized” as a whole.

In the example illustrated in FIG. 1, the first optical component 10 is a cube-shaped polarization beam splitter BS, but is not limited to this example. The first optical component 10 may be the polarization beam splitter BS of a plate type or another type. In addition to the polarization beam splitter, the first optical component 10 may include an optical element such as a prism-type reflective component. The first optical component 10 may include an antireflection film provided on the polarization beam splitter BS and other optical elements.

The second optical component 12 in the example of FIG. 1 also includes a polarization beam splitter BS similar to the polarization beam splitter BS of the first optical component 10.

### First Polarization Conversion Element

As illustrated in FIG. 1, the first polarization conversion element 20 converts the plurality of second polarization beams L2, which correspond to P-polarized light, into the plurality of third polarization beams L3, which correspond to S-polarized light. The plurality of third polarization (S-polarized) beams L3 travel in the +Z direction.

The first polarization conversion element 20 is formed of, for example, quartz or synthetic quartz, and may be a ½ wavelength plate. The ½ wavelength plate has birefringence and changes a phase difference between two orthogonal components of an electromagnetic wave traveling in a thickness direction. By arranging a slow axis or a fast axis of the ½ wavelength plate to form an angle of 45° relative to the polarization direction of the P-polarized light, the ½ wavelength plate can convert P-polarized light into S-polarized light.

In this manner, with the first optical component 10 and the first polarization conversion element 20, for example, the plurality of first polarization beams L1 and the plurality of third polarization beams L3 that are linearly polarized in the same specific direction can be obtained from the plurality of laser beams L that are non-polarized as a whole. At this stage, the plurality of first polarization (S-polarized) beams L1 are composed of a plurality of laser beams that have different peak wavelengths and are not coaxially combined. The same applies to the plurality of third polarization (S-polarized) beams L3.

Unlike the example illustrated in FIG. 1, the polarization surface 10R of the first optical component 10 may reflect the P-polarization components of the laser beams L and transmit the S-polarization components of the laser beams L. In this case, the plurality of second polarization (P-polarized) beams L2 reflected by the polarization surface 10R of the first optical component 10 travel in the −X direction, and the plurality of first polarization (S-polarized) beams L1 transmitted through the polarization surface 10R of the first optical component 10 travel in the +Z direction. The first polarization conversion element 20 is disposed at a position where the plurality of second polarization (P-polarized) beams L2 pass, and converts the plurality of second polarization (P-polarized) beams L2 into the plurality of third polarization beams L3.

The phase difference formed by the ½ wavelength plate depends on the wavelength of the incident light. Therefore, when the three second polarization beams L2 having the peak wavelengths of λ1, λ2, and λ3 pass through the ½ wavelength plate, the phase differences of exactly ½ wavelengths are not formed at all the peak wavelengths, and the P-polarization components remain in the S-polarized light converted from the P-polarized light. Therefore, in the plurality of third polarization beams L3 emitted from the first polarization conversion element 20, the P-polarization components remain, and, more specifically, elliptically polarized light may be included.

However, if all of the plurality of peak wavelengths λn are included in a relatively narrow range, for example, a range of 50 nm or less (preferably 10 nm or less), the difference in phase difference (chromatic dispersion) due to the ½ wavelength plate is sufficiently small. Therefore, the second polarization beam L2 may mainly include the S-polarization component and may partially include the P-polarization component.

The second polarization conversion element 22 can also have a configuration similar to that of the first polarization conversion element 20.

### First Mirror and Second Mirror

Each of the plurality of first mirrors 30A is disposed to reflect a respective one of the plurality of first polarization beams L1 towards the first diffraction position P1 as illustrated in FIG. 1. A first diffraction grating 40 functioning as the first diffraction element 40A is disposed at the first diffraction position P1. The plurality of first polarization beams L1 reflected by the plurality of first mirrors 30A travel parallel to the XZ plane and are incident on the predetermined region (first diffraction position P1) of the first diffraction element 40A. Similarly, each of the plurality of second mirrors 30B is disposed to reflect a respective one of the plurality of third polarization beams L3 towards the second diffraction position P2. A second diffraction grating 40 functioning as the second diffraction element 40B is disposed at the second diffraction position P2. The plurality of third polarization beams L3 reflected by the plurality of second mirrors 30B travel parallel to the XZ plane and are incident on the predetermined region (second diffraction position P2) of the second diffraction element 40B.

The positions and angles of the plurality of first mirrors 30A and the plurality of second mirrors 30B are determined such that the first wavelength-combined beam CL1 diffracted by the first diffraction element 40A at the first diffraction position P1 and the second wavelength-combined beam CL2 diffracted by the second diffraction element 40B at the second diffraction position P2 are orthogonal to each other in the second optical component 12.

The reflection by the plurality of first mirrors 30A and the plurality of second mirrors 30B does not change the polarization direction of the plurality of first polarization beams L1 and third polarization beams L3, respectively.

The first mirrors 30A and the second mirrors 30B may be formed, for example, by providing a dielectric multilayer film having a small optical loss on heat-resistant glass. The dielectric multilayer film has a reflectance of almost 100% in a wavelength range called a stopband.

If all of the plurality of peak wavelengths λn are included in the stopband, the plurality of first mirrors 30A and the plurality of second mirrors 30B may be formed of the same dielectric multilayer film. If optical loss is not taken into consideration, the plurality of first mirrors 30A and the plurality of second mirrors 30B may be formed of a metal material.

### Diffraction Element

In this embodiment, the first diffraction element 40A and the second diffraction element 40B have the same structure. To be more specific, the first diffraction element 40A and the second diffraction element 40B are constituted by the diffraction gratings 40 having the same structure. The diffraction grating 40 is formed of, for example, quartz or synthetic quartz. Hereinafter, the diffraction grating 40 including the first diffraction element 40A may be referred to as a “first diffraction grating,” and the diffraction grating 40 including the second diffraction element 40B may be referred to as a “second diffraction grating” for distinction.

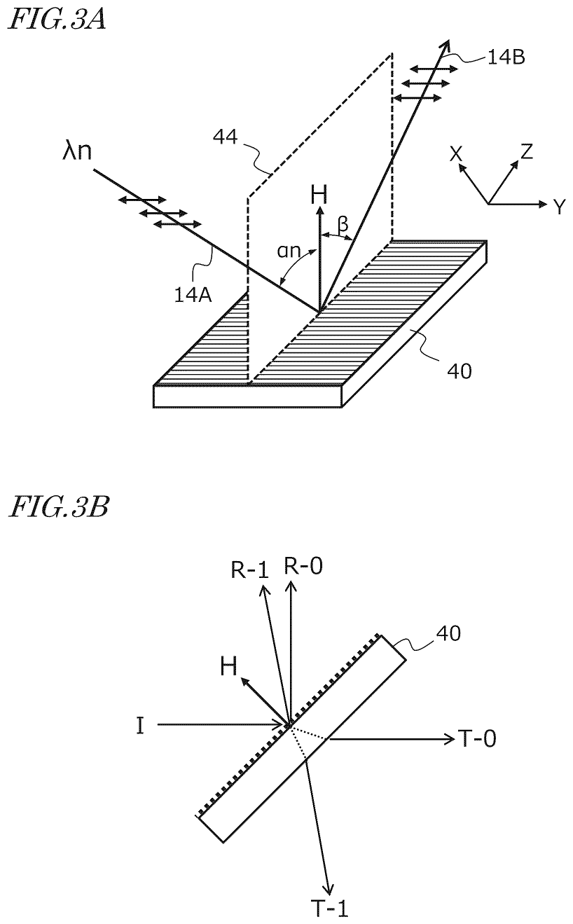

FIG. 3A is a perspective view schematically illustrating a state in which an incident ray 14A having a peak wavelength an enters the diffraction grating 40 and is diffracted to form a diffracted ray 14B. The number of diffracted rays 14B that can be formed is not limited to one. For the sake of simplicity, only one of the plurality of diffracted rays 14B is illustrated in the FIG. 3A. The incident ray 14A is representative of a ray included in each of the plurality of first polarization beams L1 or a ray included in each of the plurality of third polarization beams L3.

The incident angle of the incident ray 14A is an. The “n” of the incident angle αn is the same integer as the “n” of the peak wavelength λn. The incident angle αn is an angle formed by the normal direction H normal to the diffraction surface of the diffraction grating 40 and the incident ray 14A of the peak wavelength λn. A large number of diffraction grooves extending in the Y direction are formed in a surface of the diffraction grating 40.

A plane 44 parallel to the XZ plane is illustrated in FIG. 3A. The plane 44 is a plane including the incident ray 14A and the diffracted ray 14B, and is orthogonal to the diffraction grooves. Diffractions are phenomena (dispersions) in which the angle between the incident ray 14A and the diffracted ray 14B in the plane 44 varies in accordance with the wavelengths.

When the diffraction angle of the diffracted ray 14B is β, the relationship of the following Expression 1 is established.

$$sin ( α n ) + sin ( β ) = N \cdot m \cdot λ n \qquad ( 1 )$$

Here, N is the number of diffraction grooves per 1 mm of the diffraction grating 40, and m is the diffractive order. N can be in a range of 1000/mm to 5000/mm, for example.

For example, when the diffractive order m is 1 and the diffraction angle β is 45.0 degrees, if N=2500 and the wavelength an is 450 nm, the incident angle αn is 24.7 degrees. When a plurality of laser beams having different peak wavelengths λn are incident on the same position of the diffraction grating 40, the plurality of laser beams having different peak wavelengths λn can be diffracted in the direction of the same diffraction angle β by appropriately selecting the wavelength an and the incident angle αn.

As described above, in the present embodiment, the relationship of λ1<λ2<λ3 is established. In a case in which the plurality of laser beams L having the peak wavelengths λ1, λ2, and λ3 are incident on the diffraction grating 40, when the diffracted light is formed at the same diffraction angle β, a relationship of α1<α2<α3 is established for the incident angle αn.

FIG. 3B is a cross-sectional view schematically illustrating main diffracted rays formed when the ray I is incident on the transmissive diffraction grating 40. In FIG. 3B, a reflected zero order diffracted ray R-0, a reflected first order diffracted ray R-1, a transmitted zero order diffracted ray T-0, and a transmitted first order diffracted ray T-1, which are formed by the diffraction grating 40, are illustrated. Although the diffraction grating 40 in this embodiment is a transmissive diffraction grating, the diffraction grating 40 in this embodiment is configured such that the reflected first order diffracted ray R-1 is selectively generated with high intensity. Therefore, the reflected zero order diffracted ray R-0, the transmitted zero order diffracted ray T-0, and the transmitted first order diffracted ray T-1 generated by the transmissive diffraction grating 40 can be ignored. As a result, most of the laser beam incident on the diffraction grating is not absorbed by the material constituting the diffraction grating 40, and the loss of light is reduced. In contrast to a transmissive diffraction grating, a reflective diffraction grating includes a component for reflection, such as a dielectric multilayer film or a mirror, and light absorption by this component is not negligible. Therefore, with the reflective diffraction grating, when the intensity of the incident laser beam becomes high, there is a possibility that heat generation due to light absorption may deteriorate the performance of the diffraction grating. The base material of the diffraction grating 40 may be formed of a material having a low absorptance at the peak wavelength of the laser beam, for example, quartz or synthetic quartz. The cross-sectional shape of the grating is, for example, rectangular or trapezoidal.

Alight absorbing component may be provided on an inner lateral surface of a housing that houses the components of the wavelength beam combining device 100. The light absorbing component absorbs diffracted rays other than the reflected first order diffracted ray R-1, and reduces the occurrence of stray light.

As described above, by appropriately selecting the wavelengths λn and the incident angles αn, a plurality of first polarization beams L1 having different peak wavelengths λn can be diffracted in the direction of the same diffraction angle β. The same applies to the plurality of third polarization beams L3 having different peak wavelengths λn.

In the present embodiment, the S-polarized polarization beam L1 or the S-polarized polarization beam L3 is incident on the diffraction grating 40. In the case where the diffraction grating 40 has polarized light dependency, when a non-polarized laser beam enters the diffraction grating 40, the diffraction efficiency may decrease depending on the polarization component. In the diffraction grating 40 having a plurality of diffraction grooves parallel to the Y direction that is the first polarization direction, the diffraction efficiency of the S-polarized light is higher than the diffraction efficiency of the P-polarized light. Therefore, the diffraction grating 40 can effectively diffract the S-polarized polarization beams L1 and L3.

In a case in which the laser beam L has a spectral width of Δλn with a peak wavelength λn as a substantial center, the spectral width Δλn is preferably as small as possible. When the spectral width Δλn is widened, the diffraction angle R has a large range, which increases a range in the traveling direction of the wavelength-combined beams CL1 and CL2. The spectral width Δλn is set to, for example, 0.3 nm or less. By combining a plurality of laser beams L having narrow spectral widths Δλn, wavelength-combined beams CL1 and CL2 including a plurality of peak wavelengths in a predetermined wavelength range can be formed, and output and light density thereof can be effectively increased.

In the example of FIG. 1, the diffraction element 40A or 40B constituted by a single diffraction grating 40 is disposed on the same optical path. Because an unnecessary diffracted ray is generated by the diffraction of the diffraction grating 40, the optical loss can be reduced more in the case where one diffraction grating is disposed on the same optical path than in the case where two diffraction gratings are disposed on the same optical path.

In the example of FIG. 1, the first diffraction element 40A is disposed to emit the first wavelength-combined beam CL1 from the first diffraction position P1 in the −X direction. In contrast, the second diffraction element 40B is disposed to emit the second wavelength-combined beam CL2 from the second diffraction position P2 in the +Z direction. More specifically, the first wavelength-combined beam CL1 and the second wavelength-combined beam CL2 are on the same plane parallel to the XZ plane and are orthogonal to each other. The positions and orientations of the first diffraction element 40A and the second diffraction element 40B are determined such that the first wavelength-combined beam CL1 and the second wavelength-combined beam CL2 are incident on the polarization surface 12R of the second optical component 12 (polarization beam splitter BS) at an angle of 45°.

In the present embodiment, the first diffraction element 40A and the second diffraction element 40B are disposed such that the first wavelength-combined beam CL1 and the second wavelength-combined beam CL2 are orthogonal to each other, and the first wavelength-combined beam CL1 and the second wavelength-combined beam CL2 are incident on the second optical component 12 from directions orthogonal to each other.

### Second Polarization Conversion Element

In the example illustrated in FIG. 1, the second polarization conversion element 22 converts the second wavelength-combined beam CL2, which is S-polarized light, into P-polarized light. As a result, the polarization direction of the first wavelength-combined beam CL1 and the polarization direction of the second wavelength-combined beam CL2 are orthogonal to each other. The configuration of the second polarization conversion element 22 may be similar to the configuration of the first polarization conversion element 20.

### Second Optical Component

The second optical component 12 in the example of FIG. 1 is constituted by a polarization beam splitter BS having a polarization surface 12R. Similarly to the polarization surface 10R, the polarization surface 12R reflects the S-polarized light and transmits the P-polarized light. The second optical component 12 performs polarization-combining of the first wavelength-combined beam CL1 and the second wavelength-combined beam CL2. The second optical component 12 coaxially combines the first wavelength-combined beam CL1 and the second wavelength-combined beam CL2, and emits the combined beam in the +Z direction as a third wavelength-combined beam CL3.

The polarization surface 12R of the second optical component 12 may transmit the S-polarized light and reflect the P-polarized light. In this case, the second polarization conversion element 22 on the optical path of the second wavelength-combined beam CL2 may be moved onto the optical path of the first wavelength-combined beam CL1. When the position of the second polarization conversion element 22 is not changed, the third wavelength-combined beam CL3 emitted from the second optical component 12 travels in the −X direction, and therefore the condensing lens 50 and the optical fiber 60 may be disposed on the optical path of the third wavelength-combined beam CL3.

### Condensing Lens and Optical Fiber

The condensing lens 50 is disposed at a position where the third wavelength-combined beam CL3 is received, and condenses the third wavelength-combined beam CL3 such that it is incident on the optical fiber 60. The optical axis of the condensing lens 50 is parallel to the traveling direction of the third wavelength-combined beam CL3. The focal point of the condensing lens 50 is located at the incident end surface of the optical fiber 60. The condensing lens 50 may be a single lens or may be a combination of a plurality of lenses. The condensing lens 50 is formed of, for example, quartz or synthetic quartz.

The optical fiber 60 emits the third wavelength-combined beam CL3 incident on the incident end surfaces from the emission end surfaces. The optical fiber 60 has an appropriate length and can be bent, and thus the third wavelength-combined beam CL3 can be emitted from the emission end surfaces of the optical fiber 60 in an appropriate direction.

### Modified Example of First Embodiment

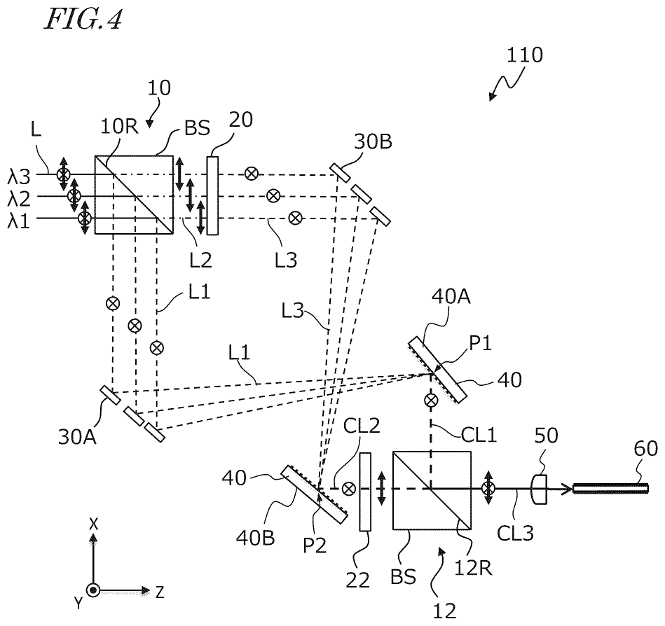

FIG. 4 illustrates a configuration of a wavelength beam combining device 110 which is a modified example of the embodiment illustrated in FIG. 1. The difference between the configuration of the wavelength beam combining device 110 illustrated in FIG. 4 and the configuration of the wavelength beam combining device 100 illustrated in FIG. 1 is the arrangement of the laser beams L having the peak wavelengths λ1, λ2, and λ3 (λ1<λ2<λ3). In the wavelength beam combining device 100 of FIG. 1, the laser beam L having the shortest peak wavelength λ1 is located on the upper side (+X direction side) of the drawing, and the laser beam L having the longest peak wavelength λ3 is located on the lower side (−X direction side) of the drawing. On the other hand, in the wavelength beam combining device 110 of FIG. 4, the laser beam L having the longest peak wavelength λ3 is located on the upper side (+X direction side) of the drawing, and the laser beam L having the shortest peak wavelength λ1 is located on the lower side (−X direction side) of the drawing.

In accordance with such a difference in the arrangement of the laser beams L, the plurality of first mirrors 30A and the plurality of second mirrors 30B are disposed such that α1<α2<α3 is satisfied for the incident angle α1 when the first polarization beam L1 is incident on the first diffraction element 40A and the incident angle α3 when the third polarization beam L3 is incident on the second diffraction element 40B.

According to the configuration of FIG. 4, the optical path length differences of the respective optical paths of the first polarization beam L1 and the third polarization beam L3 can be substantially the same, and the beam diameters at the first diffraction position P1 and the second diffraction position P2 can be substantially the same, so that the combination efficiency to the optical fiber 60 can be increased.

In each of the configuration examples of FIGS. 1 and 4, the two diffraction gratings 40 are disposed such that the first wavelength-combined beam CL1 and the second wavelength-combined beam CL2 are orthogonal to each other. The polarization surface 12R of the polarization beam splitter BS in the second optical component 12 is located at a position where the first wavelength-combined beam CL1 and the second wavelength-combined beam CL2 orthogonally meet each other. In this manner, the first wavelength-combined beam CL1 and the second wavelength-combined beam CL2 are incident on the second optical component 12 from directions orthogonal to each other, and subjected to polarization-combining. However, the configuration for polarization-combining the first wavelength-combined beam CL1 and the second wavelength-combined beam CL2 is not limited to the examples of FIGS. 1 and 4.

### Second Embodiment

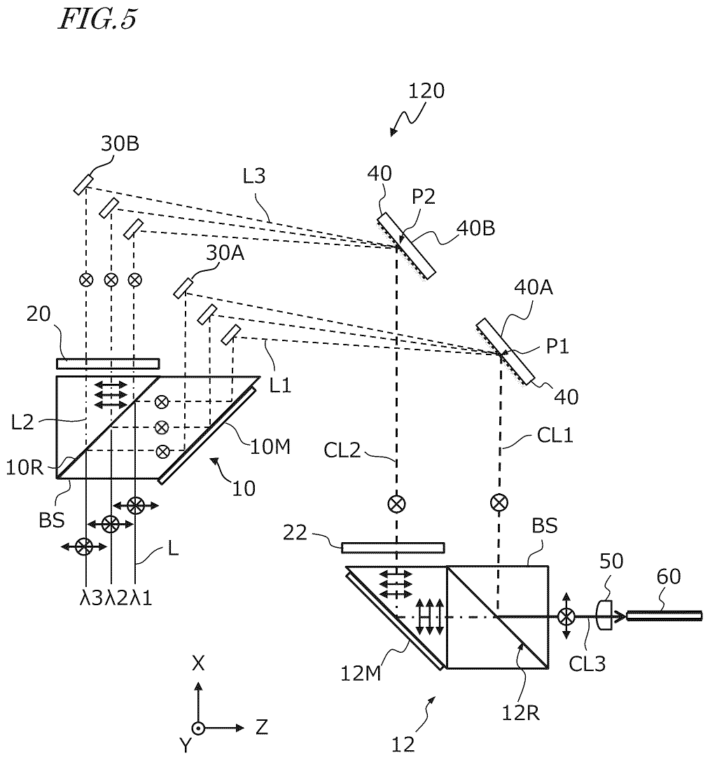

FIG. 5 illustrates a configuration example of a wavelength beam combining device 120 according to another embodiment of the present disclosure. In the wavelength beam combining device 120, the two diffraction gratings 40 are disposed such that the first wavelength-combined beam CL1 and the second wavelength-combined beam CL2 are parallel to each other, and the first wavelength-combined beam CL1 and the second wavelength-combined beam CL2 are incident on the second optical component 12 from the same direction.

Hereinafter, a configuration of the wavelength beam combining device 120 of FIG. 5 will be described. Here, components common to the components of the wavelength beam combining device 100 in FIG. 1 will not be described redundantly.

Similarly to the wavelength beam combining device 100 illustrated in FIG. 1, the wavelength beam combining device 120 illustrated in FIG. 5 includes the first optical component 10 and the second optical component 12 each of which separates or combines light, the first polarization conversion element 20 and the second polarization conversion element 22 that change the polarization state of incident light and emit the light, the plurality of first mirrors 30A and the plurality of second mirrors 30B that change the traveling direction of the incident light and reflect the incident light, and the first diffraction element 40A and the second diffraction element 40B that function as the diffraction grating 40.

The first optical component 10 has a reflection surface 10M that reflects one of the plurality of first polarization beams L1 and the plurality of second polarization beams L2 separated by the first polarization beam splitter BS. The reflection surface 10M causes the traveling direction of the plurality of first polarization beams L1 and the traveling direction of the plurality of second polarization beams L2 parallel to each other. In the example of FIG. 5, the reflection surface 10M is a part of an optical component integrated with the polarization surface 10R of the polarization beam splitter BS, and is parallel to the polarization surface 10R. To be more specific, the polarization surface 10R is located on one inclined surface of the prism component having a parallelogram cross section, and the reflection surface 10M is located on the other inclined surface. Therefore, it is not necessary to perform alignment for causing the first polarization beam L1 to be parallel to the plurality of third polarization beams L3 that has been converted from the plurality of second polarization beams L2 transmitted through the polarization surface 10R. However, the configuration of the first optical component 10 is not limited to this example. The reflection surface 10M may be another optical component separated from the polarization beam splitter BS. The reflection surface 10M is not necessarily required to be parallel to the polarization surface 10R.

In the wavelength beam combining device 120 illustrated in FIG. 5, the plurality of first polarization beams L1 and the plurality of third polarization beams L3 having exited out of the first optical component 10 travel in the direction +X and are reflected off the plurality of first mirrors 30A and the plurality of second mirrors 30B, respectively. The plurality of first mirrors 30A are positioned and oriented to direct the plurality of first polarization beams L1 to the first diffraction position P1. Similarly, the plurality of second mirrors 30B are positioned and oriented to direct the plurality of third polarization beams L3 to the second diffraction position P2. Further, the first diffraction element 40A and the second diffraction element 40B are disposed to be oriented in the same direction. As a result, the first wavelength-combined beam CL1 and the second wavelength-combined beam CL2 travel parallel to each other in the same direction (−X direction in the example of FIG. 5) from the first diffraction position P1 and the second diffraction position P2, respectively.

The traveling direction of the first wavelength-combined beam CL1 from the first diffraction position P1 and the traveling direction of the second wavelength-combined beam CL2 from the second diffraction position P2 do not necessarily have to be parallel to the −X direction as long as they are parallel to each other. By changing the positions and orientations of the plurality of first mirrors 30A and the first diffraction element 40A from the illustrated example, and similarly changing the positions and orientations of the plurality of second mirrors 30B and the second diffraction element 40B, it is possible to keep the traveling direction of the first wavelength-combined beam CL1 and the traveling direction of the second wavelength-combined beam CL2 from the second diffraction position P2 parallel to each other while they are tilted from the X direction.

In the example of FIG. 5, similarly to the first optical component 10, the second optical component 12 has the polarization surface 12R that transmits the P-polarized light and reflects the S-polarized light, and the reflection surface 12M parallel to the polarization surface 12R. The polarization direction of the second wavelength-combined beam CL2 emitted from the second diffraction position P2 is converted from the Y direction to the Z direction by the second polarization conversion element 22 (S-polarized light to P-polarized light). The reflection surface 12M reflects, in the +Z direction, the second wavelength-combined beam CL2 whose polarization direction has been converted in this manner. The second wavelength-combined beam CL2 is transmitted through the polarization surface 12R that transmits P-polarized light. On the other hand, the first wavelength-combined beam CL1 is reflected by the polarization surface 12R, and the first wavelength-combined beam CL1 and the second wavelength-combined beam CL2 are coaxially combined to form a third wavelength-combined beam. The third wavelength-combined beam CL3 is condensed by the condensing lens 50 and optically coupled to the optical fiber 60.

The configurations of the first optical component 10 and the second optical component 12 are not limited to the example of FIG. 5. The first optical component 10 and the second optical component 12 may have configurations different from each other.

In the present embodiment, the first diffraction element 40A and the second diffraction element 40B are included in different diffraction gratings 40, but two different regions of the same diffraction grating 40 may function as the first diffraction element 40A and the second diffraction element 40B.

Also in the present embodiment, the plurality of laser beams L can be incident, parallel to each other, on the first optical component 10, so that the polarization separation of the laser beams L can be efficiently performed. In addition, the single diffraction grating is placed on the optical path of each of the polarization beams (L1, L3), so that the optical loss due to the diffractions can be reduced.

### Third Embodiment

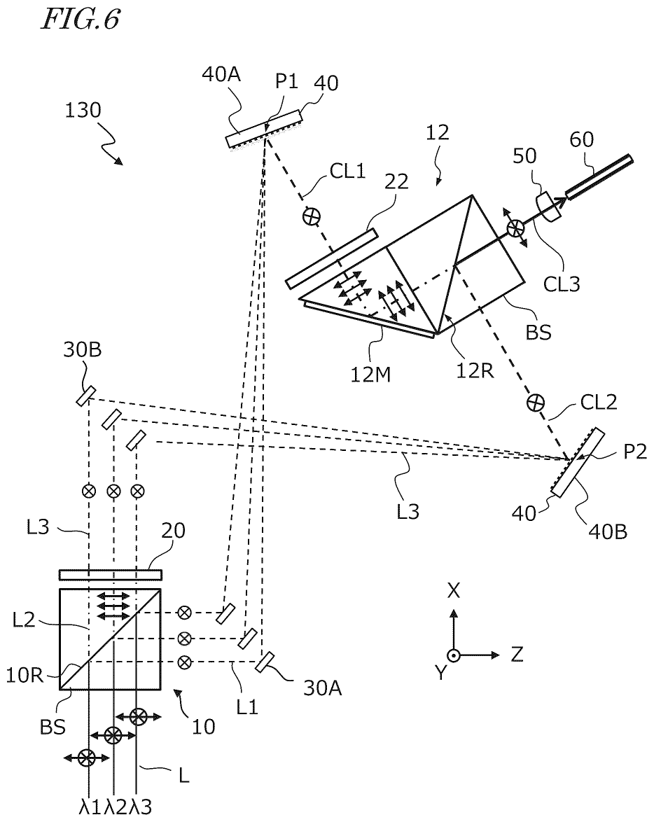

FIG. 6 illustrates a configuration example of a wavelength beam combining device 130 according to another embodiment of the present disclosure. In the wavelength beam combining device 130, the two diffraction gratings 40 are disposed such that the first wavelength-combined beam CL1 and the second wavelength-combined beam CL2 are parallel to each other and face each other (disposed in an antiparallel manner), and the first wavelength-combined beam CL1 and the second wavelength-combined beam CL2 are incident on the second optical component 12 from opposite directions.

The first optical component 10 in the wavelength beam combining device 130 of FIG. 6 does not have the reflection surface 10M. In the wavelength beam combining device 130, the distance between the first diffraction position P1 and the second diffraction position P2 is increased by adjusting the positions and the orientations of the plurality of first mirrors 30A and the plurality of second mirrors 30B, and the second optical component 12 is disposed between the first diffraction position P1 and the second diffraction position P2.

The configuration of the second optical component 12 in the wavelength beam combining device 130 is different from the configuration of the second optical component 12 in the wavelength beam combining device 120, and the polarization surface 12R is orthogonal to the reflection surface 12M. In the wavelength beam combining device 130, because the first wavelength-combined beam CL1 and the second wavelength-combined beam CL2 are incident on the second optical component 12 from the same direction to be parallel to each other and face each other, the polarization surface 12R and the reflection surface 12M are disposed parallel to each other. These second optical components 12 can be produced by combining a cube-shaped polarization beam splitter BS and a prism having a right-angled isosceles triangular cross section while changing the orientations of the polarization beam splitter BS and the prism.

Also in the present embodiment, because the plurality of laser beams L can be incident, parallel to each other, on the first optical component 10, the polarization separation of the laser beams L can be efficiently performed. In addition, because the single diffraction grating is placed on the optical path of each of the polarization beams (L1, L3), the optical loss due to the diffractions can be reduced.

In each of the embodiments described above, the first optical component 10 includes the polarization beam splitter BS (first polarization beam splitter) that separates the plurality of laser beams L into the plurality of first polarization beams L1 and the plurality of second polarization beams L2, and the second optical component 12 includes the polarization beam splitter BS (second polarization beam splitter) that combines the first wavelength-combined beam CL1 and the second wavelength-combined beam CL2. However, as described above, the second optical component 12 does not need to include the polarization beam splitter BS.

### Fourth Embodiment

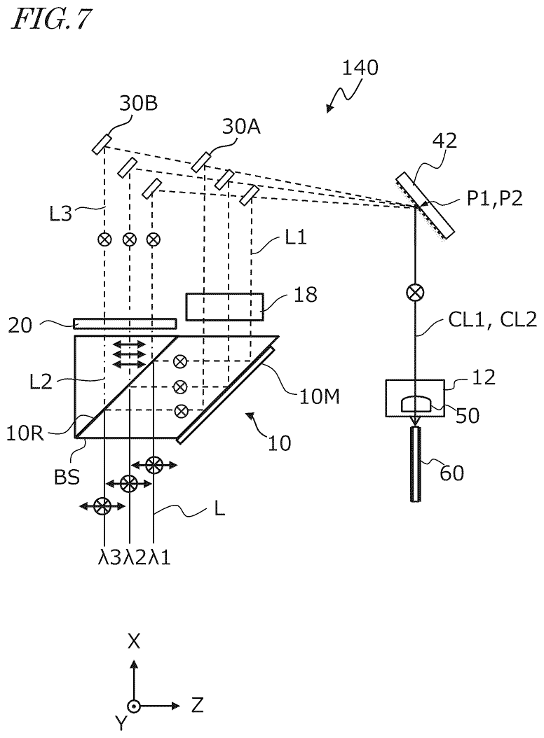

FIG. 7 illustrates a configuration example of a wavelength beam combining device 140 according to another embodiment of the present disclosure. The wavelength beam combining device 140 includes a single diffraction grating 42 including the first diffraction element 40A and the second diffraction element 40B. The diffraction grating 42 outputs the first wavelength-combined beam CL1 and the second wavelength-combined beam CL2 in the same direction. The second optical component in the present embodiment includes a lens 50 that receives and condenses the first wavelength-combined beam CL1 and the second wavelength-combined beam CL2 having exited from the diffraction gratings 42.

The first optical component 10 includes the polarization beam splitter BS that splits the plurality of laser beams L into the plurality of first polarization beams L1 and the plurality of second polarization beams L2. The first optical component 10 has the reflection surface 10M that reflects one of the plurality of first polarization beams L1 and the plurality of second polarization beams L2 separated by the polarization beam splitter BS. The reflection surface 10M makes the traveling direction of the plurality of first polarization beams L1 and the traveling direction of the plurality of second polarization beams L2 parallel to each other.

The wavelength beam combining device 140 further includes a third optical component 18 that shifts the positions of the plurality of first polarization beams L1 reflected by the reflection surface 10M of the first optical component 10 in the Y direction. The third optical component 18 is, for example, a rhomboid prism. Hereinafter, the function of the third optical component 18 will be described.

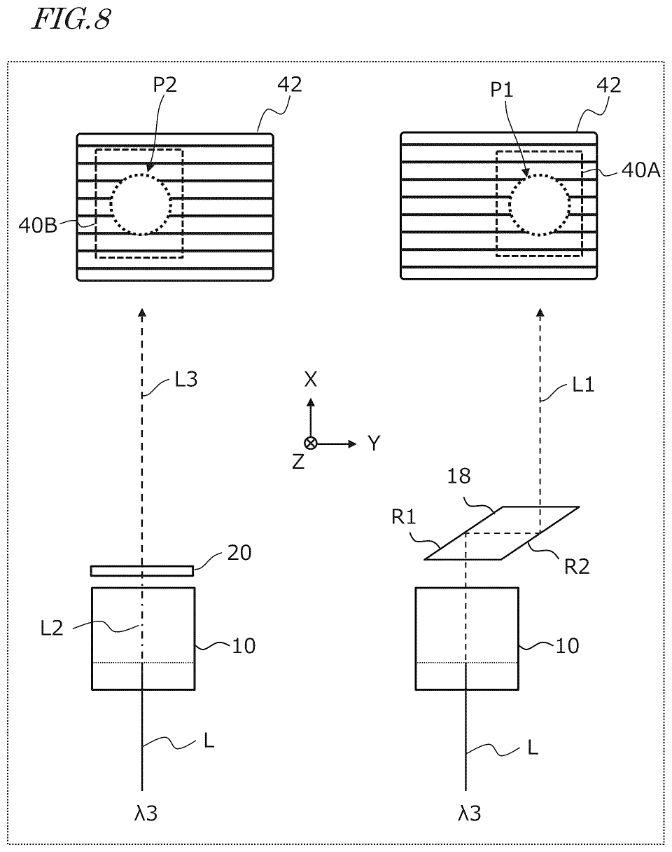

FIG. 8 is a schematic diagram for explaining the function of the third optical component 18. The right side of FIG. 8 schematically illustrates the optical path of the laser beam L having the peak wavelength λ3 as viewed from the −Z direction. More specifically, the optical path of the first polarization beam L1 separated from the laser beam L having the peak wavelength λ3 by the first optical component 10 is shifted in the +Y direction by the third optical component 18. The third optical component 18 in the example of FIG. 8 is a rhomboid prism having a pair of reflection surfaces R1 and R2 parallel to each other on its end surfaces. The rhomboid prism has a prism shape in which a cross section parallel to the XY plane is a parallelogram. The third optical component 18 may be two mirrors whose reflection surfaces are parallel to each other. On the other hand, the left side of FIG. 8 illustrates that the second polarization beam L2 separated from the laser beam L having the peak wavelength λ3 by the first optical component 10 and the third polarization beam L3 passing through the first polarization conversion element 20 travel in the +X direction without being affected by the shift effect of the third optical component 18. With such a function of the third optical component 18, the first polarization beam L1 can be shifted in the Y direction with respect to the third polarization beam L3.

Referring to FIG. 7, the optical path of the first polarization beam L1 reflected by the plurality of first mirrors 30A and the optical path of the third polarization beam L3 reflected by the plurality of second mirrors 30B appear to overlap. However, in reality, the position of the optical path of the first polarization beam L1 reflected by the plurality of first mirrors 30A is shifted in the +Y direction with respect to the position of the optical path of the third polarization beam L3 reflected by the plurality of second mirrors 30B.

A shift amount in the Y direction by the third optical component 18 is determined such that the plurality of first mirrors 30A do not interfere with the travel of the third polarization beam L3. That is, this shift amount is larger than the size of each of the plurality of first mirrors 30A in the Y direction (for example, in a range of 5 mm to 20 mm).

In the example illustrated in FIG. 8, the reflection surface R1 of the third optical component 18 reflects the first polarization beam L1 in the +Y direction, but the direction in which the reflection surface R1 reflects the first polarization beam L1 may be rotated from the +Y direction by rotating the orientation of the reflection surface R1 of the third optical component 18. The important point is to increase the distance in the Y direction between the optical path of the first polarization beam L1 and the third polarization beam L3. The plurality of first mirrors 30A and the plurality of second mirrors 30B in FIG. 7 are disposed such that the first diffraction position P1 and the second diffraction position P2 are aligned in a direction parallel to the diffraction grooves of the diffraction grating 42.

The upper part of FIG. 8 schematically illustrates the positions of the first diffraction element 40A and the second diffraction element 40B in the diffraction grating 42. The diffraction grating 42 is provided with diffraction grooves extending in the Y direction. As illustrated in FIG. 8, the first diffraction position P1 is on the first diffraction element 40A, and the second diffraction position P2 is on the second diffraction element 40B. According to the present embodiment, different regions of the single diffraction grating 42 can be used as the first diffraction element 40A and the second diffraction element 40B. Therefore, the number of diffraction gratings can be reduced.

According to the present embodiment, the first wavelength-combined beam CL1 emitted from the first diffraction position P1 and the second wavelength-combined beam CL2 emitted from the second diffraction position P2 are not strictly on the same axis. Therefore, the first wavelength-combined beam CL1 and the second wavelength-combined beam CL2 are spatially combined by the condensing lens 50 of the second optical component 12 and are incident on the optical fiber 60. From the viewpoint of increasing the combination ratio of light with respect to the optical fiber 60, it is preferable that center-to-center spacing between the first diffraction position P1 and the second diffraction position P2 on the diffraction grating 42 is short.

In this embodiment, the third optical component 18 shifts the optical path of the first polarization beam L1 in the Y direction, but the same effect can be obtained even if the optical path of the second polarization beam L2 or the third polarization beam L3 is shifted in the Y direction.

Also in the present embodiment, because the plurality of laser beams L can be incident, parallel to each other, on the first optical component 10, the polarization separation of the laser beams L can be efficiently performed. In addition, because the single diffraction grating 42 is placed on the optical path of the polarization beams (L1, L3), it is possible to reduce the optical loss due to the diffractions.

In the present embodiment, the laser beams incident on the optical fiber 60 are not obtained by polarization-combining the first wavelength-combined beam CL1 and the second wavelength-combined beam CL2. Therefore, the laser beam incident on the optical fiber 60 is linearly polarized in a specific direction (Y direction). However, the polarization state of the laser beam incident on the optical fiber 60 may change in the process of propagating through the optical fiber 60. Therefore, when the optical fiber 60 is sufficiently long, the polarization of the laser beam optically coupled to the incident end surface is broken, and the laser beam may be in a non-polarized state, for example, at the emission end surface. The same applies to the embodiments described below.

### Fifth Embodiment

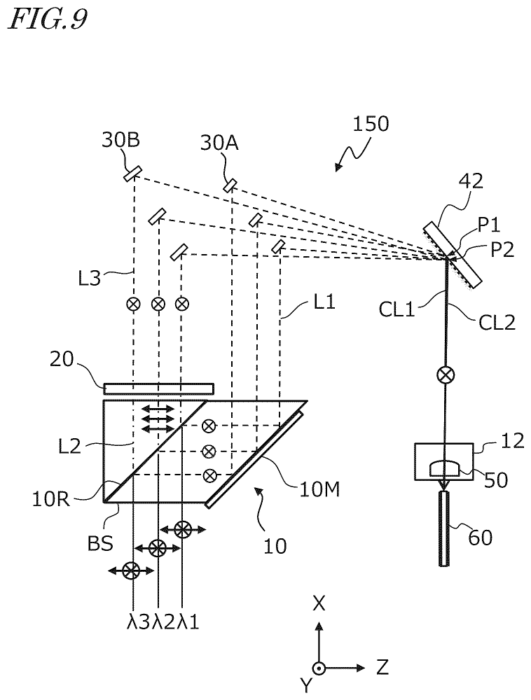

FIG. 9 illustrates a configuration example of a wavelength beam combining device 150 according to another embodiment of the present disclosure. Unlike the wavelength beam combining device 140 of FIG. 7, the wavelength beam combining device 150 does not include the third optical component 18 that shifts the optical path.

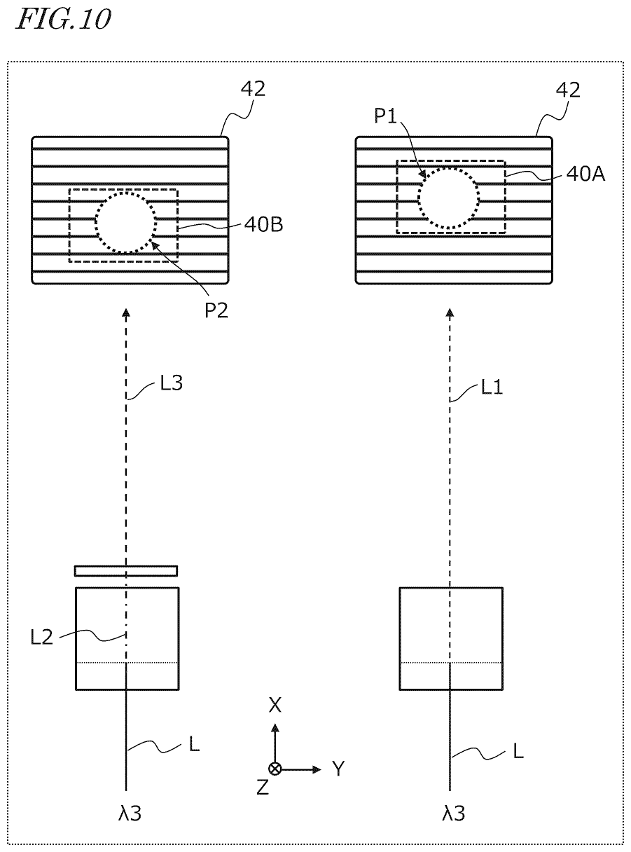

The right side of FIG. 10 schematically illustrates that the first polarization beam L1 separated by the first optical component 10 from the laser beam L having the peak wavelength λ3 viewed from the −Z direction is reflected by the reflection surface 10M and then travels in the +X direction. On the other hand, the left side of FIG. 10 schematically illustrates that the second polarization beam L2 separated from the laser beam L having the peak wavelength λ3 by the first optical component 10 and the third polarization beam L3 passing through the first polarization conversion element 20 travel in the +X direction.

As illustrated in FIG. 9, in the present embodiment, the plurality of first mirrors 30A are disposed so as not to interfere with the third polarization beams L3 reflected by the plurality of second mirrors 30B. Further, the plurality of first mirrors 30A and the plurality of second mirrors 30B are disposed such that the first diffraction position P1 and the second diffraction position P2 are aligned in a direction crossing the diffraction grooves of the diffraction grating 42.

The upper part of FIG. 10 schematically illustrates the positions of the first diffraction element 40A and the second diffraction element 40B in the diffraction grating 42. Similarly to the above-described embodiment, the diffraction grating 42 is provided with diffraction grooves extending in the Y direction. As illustrated in FIG. 10, the first diffraction position P1 is on the first diffraction element 40A, and the second diffraction position P2 is on the second diffraction element 40B. The first diffraction element 40A and the second diffraction element 40B may overlap on the diffraction grating 42.

This embodiment also allows different regions of a single diffraction grating 42 to be used as the first diffraction elements 40A and the second diffraction element 40B. Therefore, the number of diffraction gratings can be reduced.

Also in the present embodiment, the first wavelength-combined beam CL1 emitted from the first diffraction position P1 and the second wavelength-combined beam CL2 emitted from the second diffraction position P2 are not strictly on the same axis. Therefore, the first wavelength-combined beam CL1 and the second wavelength-combined beam CL2 are spatially combined by the condensing lens 50 of the second optical component 12 and are incident on the optical fiber 60. From the viewpoint of increasing the combination ratio of light with respect to the optical fiber 60, it is preferable that the center-to-center spacing between the first diffraction position P1 and the second diffraction position P2 on the diffraction grating 42 is short.

As can be seen from FIG. 9, there is a case in which a significant difference occurs between the angle at which the plurality of first polarization beams L1 directed from the plurality of first mirrors 30A toward the first diffraction position P1 are incident on the diffraction grating 42 and the angle at which the plurality of third polarization beams L3 directed from the plurality of second mirrors 30B toward the second diffraction position P2 are incident on the diffraction grating 42. It is also possible to make a pair of beams having the same wavelengths among the first polarization beams and the third polarization beams L3 incident, parallel to each other, on the diffraction grating 42 at the same angle by adjusting the positions and orientations of the plurality of first mirrors 30A and the plurality of second mirrors 30B. On the other hand, it is preferable that the difference between the diffraction angle of the first wavelength-combined beam CL1 traveling from the first diffraction position P1 toward the condensing lens 50 and the diffraction angle of the second wavelength-combined beam CL2 traveling from the second diffraction position P2 toward the condensing lens 50 is as small as possible. Because the incident angle (an) and the diffraction angle (β) have the relationship of Expression (1) described above, the first diffraction position P1 and the second diffraction position P2 cannot coincide with each other. By increasing the distances from the plurality of first mirrors 30A and the plurality of second mirrors 30B to the diffraction gratings 42, it is possible to reduce the difference in the incident angle (αn) and shorten the center-to-center spacing between the first diffraction position P1 and the second diffraction position P2.

Also in the present embodiment, because the plurality of laser beams L can be incident, parallel to each other, on the first optical component 10, the polarization separation of the laser beams L can be efficiently performed. In addition, because the single diffraction grating is placed on the optical path of the polarization beams (L1, L3), it is possible to reduce the optical loss due to the diffractions.

### Direct Diode Laser Device

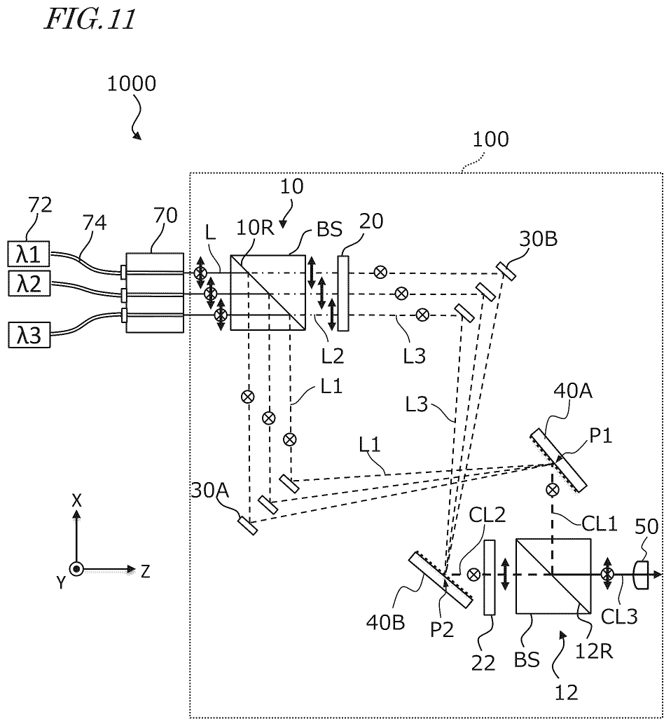

Subsequently, a configuration example of a DDL device according to an embodiment of the present disclosure will be described with reference to FIG. 11. FIG. 11 is a diagram schematically illustrating a configuration of a DDL device according to an exemplary embodiment of the present disclosure. A DDL device 1000 illustrated in FIG. 11 includes the wavelength beam combining device 100 illustrated in FIG. 1, a plurality of semiconductor laser devices 72 each of which emits laser light corresponding to one of the plurality of laser beams L, and an optical fiber array device 70 configured to form the one of the plurality of laser beams L from the laser light emitted from each of the semiconductor laser devices 72.

In the example illustrated in FIG. 11, the number of the semiconductor laser devices 72 is three, but is not limited to this example. The number of semiconductor laser devices 72 is determined according to the required light output or irradiance. The wavelength of the laser light emitted from the semiconductor laser device 72 may also be selected according to the material to be processed.

The laser light emitted from each semiconductor laser device 72 is optically coupled to the corresponding optical fiber 74 of the optical fiber array device 70. The plurality of semiconductor laser devices 72 are configured to oscillate laser light beams at peak wavelengths different from each other. Even if the laser light emitted from each semiconductor laser device 72 is linearly polarized light, when the optical fiber 74 is not a polarization maintaining fiber, the polarization state of the laser light changes in the process of passing through the optical fiber 74. Therefore, the plurality of laser beams L formed by the optical fiber array device 70 are non-polarized.

Examples of the semiconductor laser device 72 include an external cavity laser (ECL) device, a distributed feedback (DFB) laser device, and a distributed Bragg reflector (DBR) laser device.

The optical fibers 74 can be aligned by the optical fiber array device 70, and the emission angle of the laser beam L can be easily adjusted. This can facilitate emission of the plurality of laser beams L parallel to each other with high precision from the optical fiber array device 70. An optical fiber extending from the semiconductor laser device 72 may be fused and connected to the optical fiber 74 of the optical fiber array device 70. The optical fiber array device 70 includes a lens system that collimates the laser light emitted from the distal end of each optical fiber 74.

In the DDL device 1000 according to the present embodiment, the wavelength-combined beam CL3 can be formed from the plurality of non-polarized laser beams L by the wavelength beam combining device 100 even if the laser light emitted from the plurality of semiconductor laser devices 72 is non-polarized by the optical fiber array device 70.

The DDL device 1000 may include other wavelength beam combining devices 110, 120, 130, 140, and 150 in place of the wavelength beam combining device 100.

### Laser Processing Machine

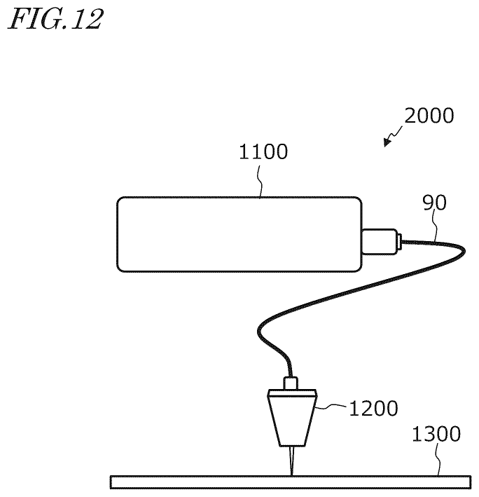

Subsequently, a configuration example of a laser processing machine according to an embodiment of the present disclosure will be described with reference to FIG. 12. FIG. 12 is a schematic diagram illustrating a configuration of a laser processing machine according to an exemplary embodiment of the present embodiment. A laser processing machine 2000 illustrated in FIG. 12 includes a light source device 1100 that is the DDL device 1000 illustrated in FIG. 11, an optical transmission fiber 90 that extends from the light source device 1100 and is coupled to a wavelength-combined beam CL3 emitted from the light source device 1100, and a processing head 1200 connected to the optical transmission fiber 90. The processing head 1200 irradiates an object 1300 with the wavelength-combined beam CL3 emitted from the optical transmission fiber 90.

In the example illustrated in FIG. 12, the number of light source devices 1100 is one, but the number of light source devices 1100 is not limited to this example. The processing head 1200 may be connected to the plurality of light source devices 1100 via the optical transmission fiber 90.

In the laser processing machine 2000 according to the present embodiment, because a high-power laser beam is generated by wavelength beam combining and efficiently combined to an optical fiber, it is possible to obtain a high-power-density laser beam having excellent beam quality with high energy conversion efficiency.

The laser beam emitted from the processing head 1200 may include a laser beam other than the combined laser beam emitted from the semiconductor laser device 72 illustrated in FIG. 11. For example, the peak wavelengths of the laser beams emitted from the semiconductor laser devices 72 and wavelength-combined are included in wavelengths in a range from 430 nm to 480 nm, and additionally, for example, laser beams having near infrared peak wavelengths may be combined. Depending on the material to be processed, a laser beam having a wavelength at which the material has a high light absorptance may be combined as appropriate.

A wavelength beam combining device, a direct diode laser device, and a laser processing machine of the present disclosure can be widely used in applications requiring high output and high power density laser light with high beam quality, such as cutting, drilling, local heat treatment, surface treatment of various materials, welding of metal, 3D printing, and the like.

What is claimed is:

1. A wavelength beam combining device for combining a plurality of laser beams having different peak wavelengths, the wavelength beam combining device comprising:
a first optical component configured to separate the plurality of laser beams into a plurality of first polarization beams linearly polarized in a first polarization direction and a plurality of second polarization beams linearly polarized in a second polarization direction orthogonal to the first polarization direction;
a first polarization conversion element configured to convert the plurality of second polarization beams into a plurality of third polarization beams linearly polarized in the first polarization direction;
a plurality of first mirrors each configured to reflect a respective one of the plurality of first polarization beams towards a first diffraction position;
a plurality of second mirrors each configured to reflect a respective one of the plurality of third polarization beams towards a second diffraction position;
a first diffraction element configured to receive, at the first diffraction position, the plurality of first polarization beams reflected by the plurality of first mirrors and diffract the plurality of first polarization beams to form a first wavelength-combined beam in which the plurality of first polarization beams are coaxially combined;
a second diffraction element configured to receive, at the second diffraction position, the plurality of third polarization beams reflected by the plurality of second mirrors and diffract the plurality of third polarization beams to form a second wavelength-combined beam in which the plurality of third polarization beams are coaxially combined; and
a second optical component on which the first wavelength-combined beam and the second wavelength-combined beam are incident.

2. The wavelength beam combining device according to claim 1, comprising:
a first diffraction grating comprising the first diffraction element;
a second diffraction grating comprising the second diffraction element;
a second polarization conversion element configured to convert a polarization state of at least one of the first wavelength-combined beam or the second wavelength-combined beam such that polarization directions of the first wavelength-combined beam and the second wavelength-combined beam are orthogonal to each other, wherein:
the second optical component is configured to form and emit a third wavelength-combined beam in which the first wavelength-combined beam and the second wavelength-combined beam are coaxially combined.

3. The wavelength beam combining device according to claim 2, wherein:
each of the first diffraction grating and the second diffraction grating has a plurality of diffraction grooves extending in the first polarization direction.

4. The wavelength beam combining device according to claim 3, wherein:
the first optical component comprises a first polarization beam splitter configured to separate the plurality of laser beams into the plurality of first polarization beams and the plurality of second polarization beams, and
the second optical component comprises a second polarization beam splitter configured to combine the first wavelength-combined beam and the second wavelength-combined beam.

5. The wavelength beam combining device according to claim 4, wherein:
the first diffraction grating and the second diffraction grating are disposed such that the first wavelength-combined beam and the second wavelength-combined beam are orthogonal to each other, the first diffraction grating and the second diffraction grating being configured to cause the first wavelength-combined beam and the second wavelength-combined beam to be incident on the second optical component from directions orthogonal to each other.

6. The wavelength beam combining device according to claim 2, comprising:
a lens configured to condense the third wavelength-combined beam.

7. The wavelength beam combining device according to claim 4, wherein:
the first optical component comprises a reflection surface configured to reflect one of the plurality of first polarization beams and the plurality of second polarization beams separated by the first polarization beam splitter, the reflection surface being configured to cause a traveling direction of the plurality of first polarization beams and a traveling direction of the plurality of second polarization beams to be parallel to each other.

8. The wavelength beam combining device according to claim 7, wherein:
the first diffraction grating and the second diffraction grating are disposed such that the first wavelength-combined beam and the second wavelength-combined beam are parallel, the first diffraction grating and the second diffraction grating being configured to cause the first wavelength-combined beam and the second wavelength-combined beam to be incident on the second optical component from a same direction.

9. The wavelength beam combining device according to claim 7, wherein:
the first diffraction grating and the second diffraction grating are disposed such that the first wavelength-combined beam and the second wavelength-combined beam are antiparallel to each other, the first diffraction grating and the second diffraction grating being configured to cause the first wavelength-combined beam and the second wavelength-combined beam to be incident on the second optical component from directions opposite to each other.

10. The wavelength beam combining device according to claim 1, comprising:
a single diffraction grating comprising the first diffraction element and the second diffraction element, wherein:
the diffraction grating is configured to cause the first wavelength-combined beam and the second wavelength-combined beam to exit in a same direction, and
the second optical component comprises a lens configured to receive and condense the first wavelength-combined beam and the second wavelength-combined beam that have exited from the diffraction grating.

11. The wavelength beam combining device according to claim 10, wherein:
the first optical component comprises a polarization beam splitter configured to separate the plurality of laser beams into the plurality of first polarization beams and the plurality of second polarization beams, and
the first optical component comprises a reflection surface configured to reflect one of the plurality of first polarization beams and the plurality of second polarization beams separated by the polarization beam splitter, the reflection surface being configured to cause a traveling direction of the plurality of first polarization beams and a traveling direction of the plurality of second polarization beams to be parallel to each other.

12. The wavelength beam combining device according to claim 11, wherein:
the diffraction grating has a plurality of diffraction grooves extending in the first polarization direction.

13. The wavelength beam combining device according to claim 12, further comprising:
a third optical component configured to shift, in the first polarization direction, positions of the plurality of first polarization beams reflected by the reflection surface of the first optical component, wherein:
the plurality of first mirrors and the plurality of second mirrors are disposed such that the first diffraction position and the second diffraction position are aligned in a direction parallel to the plurality of diffraction grooves of the diffraction grating.

14. The wavelength beam combining device according to claim 12, wherein:
the plurality of first mirrors and the plurality of second mirrors are disposed such that the first diffraction position and the second diffraction position are aligned in a direction crossing the plurality of diffraction grooves of the diffraction grating.

15. A direct diode laser device comprising:
the wavelength beam combining device according to claim 1; and
a laser light source configured to emit a plurality of laser beams parallel to each other.

16. The direct diode laser device according to claim 15, wherein:
the laser light source comprises:
a plurality of semiconductor laser elements, and
a plurality of optical fibers each coupled to a respective one of the plurality of semiconductor laser elements.

17. A laser processing machine comprising:
at least one direct diode laser device being the direct diode laser device according to claim 15;
an optical transmission fiber to be coupled to a laser beam emitted from the at least one direct diode laser device; and
a processing head connected to the optical transmission fiber.
